(19) United States
(12) Patent Application Publication
(10) Pub. No.: US 2007/0284675 A1
(43) Pub. Date: Dec. 13, 2007

(54) SEMICONDUCTOR DEVICE AND METHOD FOR MANUFACTURING SAME

(75) Inventors: Naohiko Kimizuka, Kanagawa (JP); Yasushi Nakahara, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki (JP)

(21) Appl. No.: 11/747,785

(22) Filed: May 11, 2007

(30) Foreign Application Priority Data
May 29, 2006 (JP) 2006-148381

(51) Int. Cl. H01L 29/94

(52) U.S. Cl. 257/410; 257/412

(57) ABSTRACT

The semiconductor device includes a silicon substrate, an SiO₂ film provided so as to be in contact with the upper portion of the silicon substrate, and a p-type MOSFET including a polycrystalline silicon film, which is provided so as to be in contact with the upper portion of the SiO₂ film. Further, an interior of the SiO₂ film or an interface of the SiO₂ film with the polycrystalline silicon film is provided with a region containing at least one metallic element of Hf and Zr at an area density of not higher than 1.3×10¹⁴ atoms/cm².

This application is based on Japanese patent application No. 2006-148,381, the content of which is incorporated hereinto by reference.

### BACKGROUND

1. Technical Field

The present invention relates to a semiconductor device including a metal oxide semiconductor field effect transistor (MOSFET) and method for manufacturing thereof.

2. Related Art

Due to a remarkable miniaturization of semiconductor devices in recent years, various innovations are required for the purpose of assuring performances and a reliability of a MOSFET. In such circumstances, an utilization of a film having high dielectric constant called high-k film as a gate insulating film is actively investigated for obtaining an improved performances of the MOSFET. Typical high-k materials include oxides of elements such as zirconium (Zr), hafnium (Hf) and the like. A use of such material for a gate insulating film of a MOSFET reduces a silicon oxide-converted electrical thickness, even though the physical thickness of the gate insulating film is increased by a certain level, thereby providing a physically and structurally stable gate insulating film. Thus, an increase of metal oxide semiconductor (MOS) capacity for enhancing MOSFET characteristics and/or a reduction of a gate leakage current as compared with a conventional case of employing silicon oxide can be achieved.

However, it has been widely known that a phenomenon called Fermi level pinning is caused when a gate insulating film is composed of a high-k film and the gate electrode is composed of a polycrystalline silicon (Japanese Patent Laid-Open No. 2005-340,329). It is considered that Fermi level pinning is caused when a certain energy level is created on the basis of a bond between silicon and the above-described metallic element for composing the high-dielectric constant film, in vicinity of an interface on the side of the gate insulating film in the gate electrode. As a result, a threshold voltage of the MOSFET is increased, and further a fluctuation in the threshold voltage is also increased, providing a factor for preventing an utilization of such high dielectric constant film. While the above description has been made in reference to the example of utilizing polycrystalline silicon for the gate electrode, the threshold voltage is often increased when a high dielectric constant film is employed for the gate insulating film.

On the other hand, in view of a reliability of a MOSFET, a phenomenon called negative bias temperature instability (NBTI) is known (Dieter K. Schroder, and Jeff A. Babcock, Journal of Applied Physics, Volume 94, Number 1, p. 1-p. 18, 2003, entitled “Negative bias temperature instability: Road to cross in deep submicron silicon semiconductor manufacturing”). An outline of such phenomenon is that in particular, the NBTI is considerably generated in p-type MOSFET, and when a negative bias voltage is applied to a gate electrode in an environment at a high-temperature, positive fixed charge is generated in the gate insulating film, leading to an increased threshold voltage. As a result, an operating speed of a MOSFET is decreased as time passes, so that the operation timings of a plurality of MOSFET are not harmonized in the semiconductor device, leading to a generation of a false operation. Although searches and investigations have been made for the NBTI in view of various aspects, it is the present situation that there are not effective countermeasures.

### SUMMARY

Meanwhile, as disclosed by Dieter K. Schroder et al. in the above-described article, strength of an electrical field applied to the gate insulating film is increased from year to year, in response to a tendency of utilizing a reduced film thickness of the gate insulating film of the MOSFET. Thus, in the generation that the gate length is below 100 nm, an increase of a threshold voltage of a p-type MOSFET due to the NBTI is relatively easily generated, as compared with generation in the earlier generations. It is a very critical problem to provide an improved NBTI resistance of a p-type MOSFET in terms of ensuring a sufficient long term reliability of semiconductor devices.

The present inventors have eagerly conducted investigations concerning the NBTI of the p-type MOSFET, which is described in the above-described article of Dieter K. Schroder et al. As a result, it was found that the NBTI resistance can be improved without substantially deteriorating the characteristics of the MOSFET, by providing a region that contains a metallic element such as Hf and the like in a trance amount 1) in the interface between the gate insulating film and the gate electrode, or 2) in the gate insulating film, which leads to achieving the present invention.

According to one aspect of the present invention, there is provided a semiconductor device comprising a p-type field effect transistor, the p-type field effect transistor comprising: a semiconductor substrate; a gate insulating film provided so as to be in contact with an upper portion of the semiconductor substrate; and a gate electrode provided so as to be in contact with an upper portion of the gate insulating film, wherein a region is included in the gate insulating film or in an interface between the gate insulating film and the gate electrode, the region containing at least one metallic element of hafnium (Hf) and zirconium (Zr) at an area density of not higher than 1.3×10¹⁴ atoms/cm².

In the present invention, the region containing at least one metallic element of Hf and Zr is presented in an interface between the gate insulating film and the gate electrode of the p-type field effect transistor or in the gate insulating film. Thus, electron is trapped by Hf or Zr or compounds thereof, and trapped electron neutralizes positive fixed charge, which has been created in the gate insulating film when a negative bias voltage was applied to the gate electrode. Thus, an increase in the threshold voltage due to the NBTI can be effectively inhibited.

Further, in the present invention, the density of at least one metallic element of Hf and Zr per unit area in the region containing such metallic element is not higher than 1.3×10¹⁴ atoms/cm². Having the configuration, in which the region containing a trace mount of such metallic element in the gate insulating film is provided, the NBTI described above can be inhibited, while inhibiting an increase of the threshold voltage caused in the case of employing a high dielectric constant film for the gate insulating film described above related to the background technology.

Further, the region containing the above-described metallic element at an area density of not higher than 1.3×10¹⁴ atoms/cm² may be formed via, for example, a sputter process with further manufacturing stably.

More specifically, according to another aspect of the present invention, there is provided a method for manufacturing the semiconductor device as described above, comprising: forming the gate insulating film on the semiconductor substrate; sputtering at least one metallic element of hafnium (Hf) and zirconium (Zr) onto the gate insulating film to form a region containing the metallic element; and forming a gate electrode film on the gate insulating film that is provided with the region, wherein, in sputtering the forming the region containing the metallic element, an area density of the metallic element in the region is equal to or lower than 1.3×10¹⁴ atoms/cm².

Further, according to further aspect of the present invention, there is provided a method for manufacturing the semiconductor device as described above, comprising: forming a first gate insulating film on the semiconductor substrate; sputtering at least one metallic element of hafnium (Hf) and zirconium (Zr) onto the first gate insulating film to form a region containing the metallic element; forming a second gate insulating film on the first gate insulating film that is provided with the region; and forming a gate electrode film on the second gate insulating film, wherein, in the forming the region containing the metallic element, an area density of the metallic element in the region is equal to or lower than 1.3×10¹⁴ atoms/cm².

According to the present invention, the configuration having the region containing at least one metallic element of Hf and Zr at an area density of not higher than 1.3×10¹⁴ atoms/cm² is employed, so that an improved NBTI resistance of the p-type field effect transistor can be effectively achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 a cross-sectional view of a semiconductor device, illustrating a configuration of a semiconductor device in an embodiment of the present invention;

FIG. 2 is a cross-sectional view of a semiconductor device, illustrating a principle of causing an NBTI on a conceptual basis;

FIG. 3 is a cross-sectional view, illustrating the configuration of the semiconductor device in the embodiment of the present invention;

FIG. 4 is a graph, showing an improvement in the NBTI resistance in the embodiment of the present invention;

FIG. 5 is a graph, showing an improvement in the NBTI resistance in the embodiment of the present invention;

FIG. 6A to FIG. 6C are cross-sectional views, illustrating an exemplary implementation of a procedure for manufacturing the semiconductor device in the embodiment of the present invention;

FIG. 7A to FIG. 7C are cross-sectional views, illustrating an exemplary implementation of a procedure for manufacturing the semiconductor device in the embodiment of the present invention;

FIG. 8 is a graph, showing a relationship of the Hf concentration with the threshold voltage of a p-type MOSFET;

FIG. 9 is a graph, showing a relationship of the Hf concentration with an uniformity in the surface;

FIG. 10 is a cross-sectional view, schematically illustrating a configuration of a semiconductor device according to an embodiment of the present invention; and

FIG. 11A to FIG. 11C are cross-sectional views, illustrating an example of a procedure for manufacturing the semiconductor device according to the embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Paragraphs below will describe embodiments of the present invention referring to the attached drawings. It is to be noted that any common constituents appear in all drawings will be given with the same reference numerals, so as to avoid repetitive explanation.

### First Embodiment

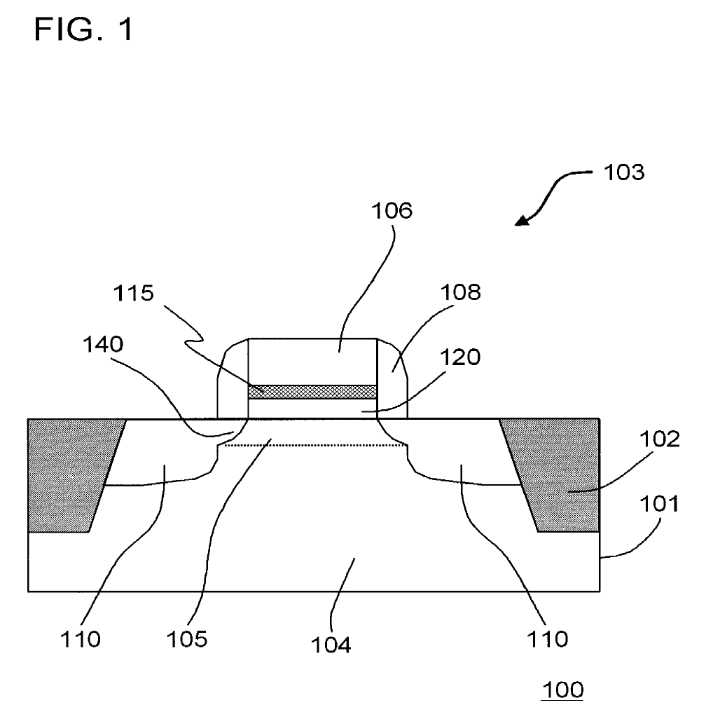

FIG. 1 is a cross-sectional view, schematically illustrating a configuration of a semiconductor device 100 according to the present embodiment. The semiconductor device 100 includes a silicon substrate 101 and a p-type MOSFET 103 provided on the silicon substrate 101. The p-type MOSFET 103 in this embodiment is a transistor having a surface channel structure. Further, a circumference portion of the p-type MOSFET 103 is provided with an element isolation region 102.

In the p-type MOSFET 103, a pair of impurity-diffused regions 110 are provided in an N-well 104, which is provided in the silicon substrate 101 and has a n-type conductivity, and a channel region 105 is formed between these impurity-diffused regions. The impurity-diffused regions 110 are diffusion layers doped with a p-type impurity in the surface of the n-well 104. One will be a source region, and the other will be a drain region. Further, extension regions 140 are provided in the n-well 104.

An SiO₂ film 120, serving as a gate insulating film, is provided so as to be in contact with the upper portion of the channel region 105, and a polycrystalline silicon film 106 is provided so as to be in contact with the upper portion of the SiO₂ film 120. The polycrystalline silicon film 106 is a p-type gate electrode film, and is doped with a p-type impurity such as boron (B) and the like. An interface of the SiO₂ film 120 serving as a gate insulating film with the polycrystalline silicon film 106 is provided with a region containing at least one metallic element of Hf and Zr at an area density of not higher than 1.3×10¹⁴ atoms/cm². With the present embodiment, an Hf layer 115 is provided as the above-described region.

The Hf layer 115 contains Hf, which is a metallic element functioning as providing an improved NBTI resistance, with a density per unit area of equal to or lower than 1.3×10¹⁴ atoms/cm², and is, for example, a layer containing Hf adsorbed on the top surface of the SiO₂ film 120. Further, the Hf layer 115 is provided in, for example, the entire interface of the SiO₂ film 120 with the polycrystalline silicon film 106. This can more stably provide an advantageous effect of inhibiting the NBTI as discussed later.

The thickness of the Hf layer 115 is equal to or shorter than 1 nm, for example. Further, atomic Hf is present in a scattered manner in the Hf layer 115. Thus, an average thickness of the Hf layer 115 in the cross-sectional view along the gate length direction may be smaller than a thickness equivalent to a layer of single atom.

Next, reasons that the presence of Hf provides an improved NBTI resistance will be described as follows.

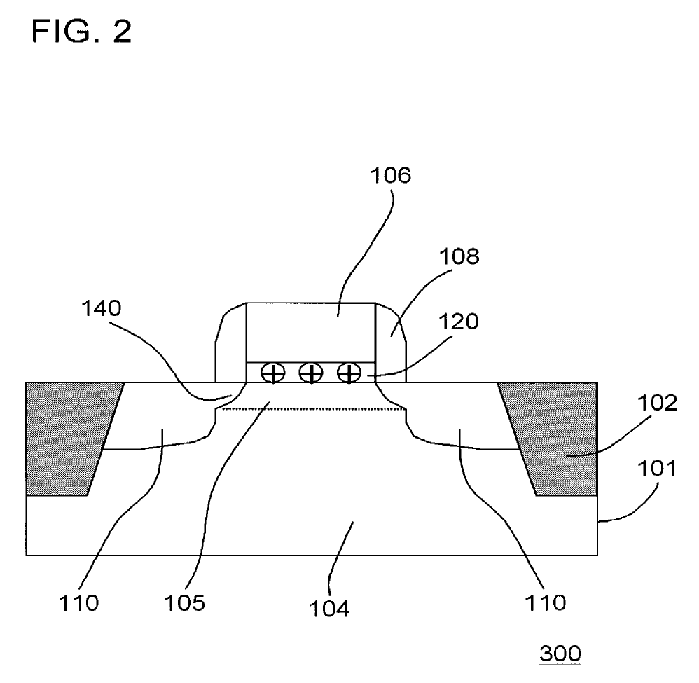

A condition of a conventional semiconductor device 300 having a conventional structure, in which a positive fixed charge is trapped in a gate insulating film of a p-type MOSFET due to the NBTI, is shown in FIG. 2 on a conceptual basis. Since the configurations shown in FIG. 2 are similar as that shown in FIG. 1 except that no Hf layer 115 is included therein, detailed descriptions is not presented here. In the case of the configuration shown in FIG. 2, as positive fixed charge in the gate insulating film is increased, higher threshold voltage is required for inducing the same amount of carrier in the channel region 105.

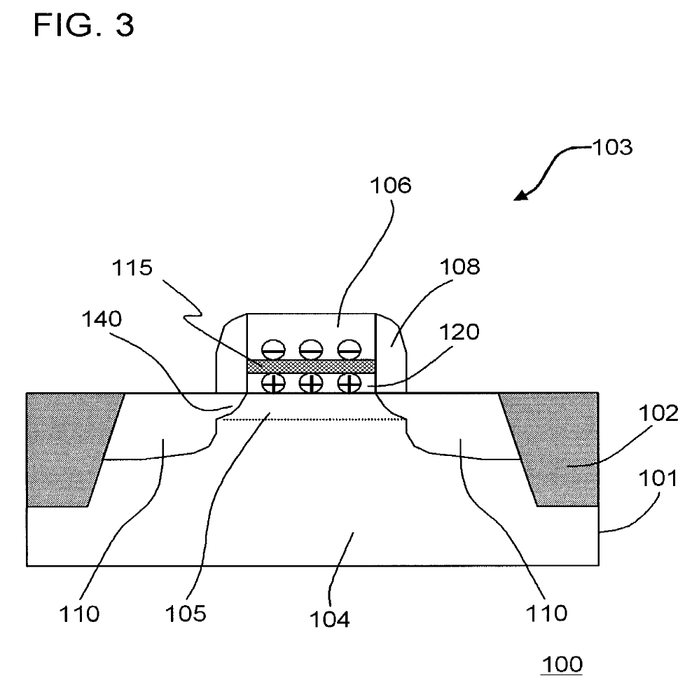

On the contrary, since the p-type MOSFET 103 having the structure shown in FIG. 1 has the Hf layer 115, Atomic Hf originated from the Hf layer 115 or a Hf-containing compound generated by contacting Hf from the Hf layer 115 with silicon in the polycrystalline silicon film 106 functions as an electron trap or an electron scavenger. This is shown in FIG. 3 on a conceptual basis. Since the structure shown in FIG. 3 is similar as that shown in FIG. 1, detailed descriptions is not presented here. It is assumed that an increase in threshold voltage is eased by electron trapped by atomic Hf or a Hf compound, which serves as neutralizing an influence of positive fixed charge generated due to the NBTI.

Further, since the polycrystalline silicon film 106 serves as the gate electrode in the present embodiment, it can be also considered that the other reason for providing an improved NBTI resistance by the presence of Hf existing in the interface between the gate insulating film and the gate electrode may be an influence of Fermi level pinning. If a metallic element for constituting the high dielectric constant film diffuses into polycrystalline silicon of the gate electrode, a depleted layer is generated in polycrystalline silicon in vicinity of the interface with the gate insulating film. An influence of such depleted layer prevents the gate insulating film from being applied with sufficient level of electric field even if the gate voltage is applied thereto, leading to a difficulty in inducing carrier in the channel region. It is considered that the reduced level of the electric field applied to the gate insulating film results in a reduced level of a phenomenon that positive fixed charge is accumulated in the gate insulating film of the p-type MOSFET.

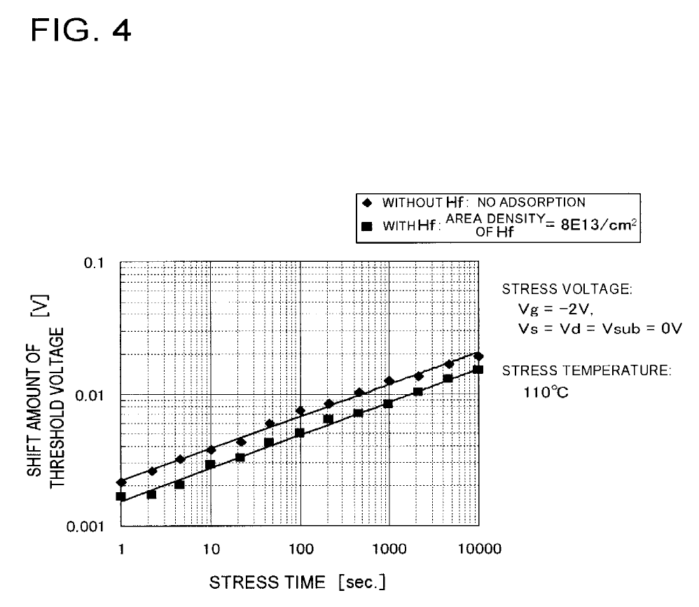

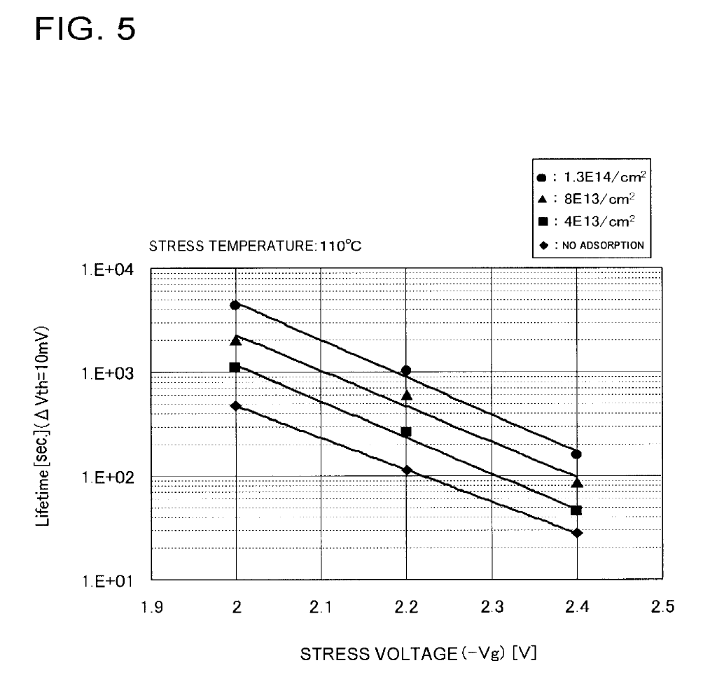

Next, results of evaluations that an improved NBTI resistance was obtained by Hf existing in the interface of the gate insulating film and the gate electrode are shown in FIG. 4 and FIG. 5.

FIG. 4 is a graph showing a relationship of a shift amount of threshold voltage (V) with a stress time (sec) for the semiconductor device shown in FIG. 1 and FIG. 2.

In FIG. 4, plots with the description of “without Hf” indicate results obtained by the semiconductor device having no Hf layer 115 (FIG. 2). Besides, plots with the description of “with Hf” indicate results obtained by the semiconductor device provided with the Hf layer 115 having Hf area density of 8×10¹³ atoms/cm² (FIG. 1). In addition to above, in these semiconductor devices, the film thickness of SiO₂ film 120 was selected to be 2.0 nm.

Further, stress conditions include stress voltages of: Vg=−2V; and Vs=Vd=Vsub=0 Volt, and stress temperature of 110 degree C.

FIG. 5 is a graph, illustrating a relationship between the stress electrical voltage −Vg (V) and the lifetime (sec) required for achieving a voltage of 10 mV for the shift amount ΔVth of threshold voltage, concerning the semiconductor devices having different Hf area density in the Hf layer 115. Here, evaluations were made for the semiconductor device (FIG. 1), which includes the Hf layers 115 having the area densities of Hf of 1.3×10¹⁴ atoms/cm², 8×10¹³ atoms/cm² and 4×10¹³ atoms/cm², provided in the entire interface between the SiO₂ film 120 and the polycrystalline silicon film 106, and the semiconductor device (FIG. 2) having no Hf layer 115. Further, in FIG. 5, the stress voltages of: Vs=Vd=Vsub=0 Volt, was also employed, and the stress temperature was set to 110 degree C.

As can be seen from FIG. 4 and FIG. 5, the NBTI caused when a negative stress voltage is applied to the gate electrode can be reduced by providing the Hf layer 115.

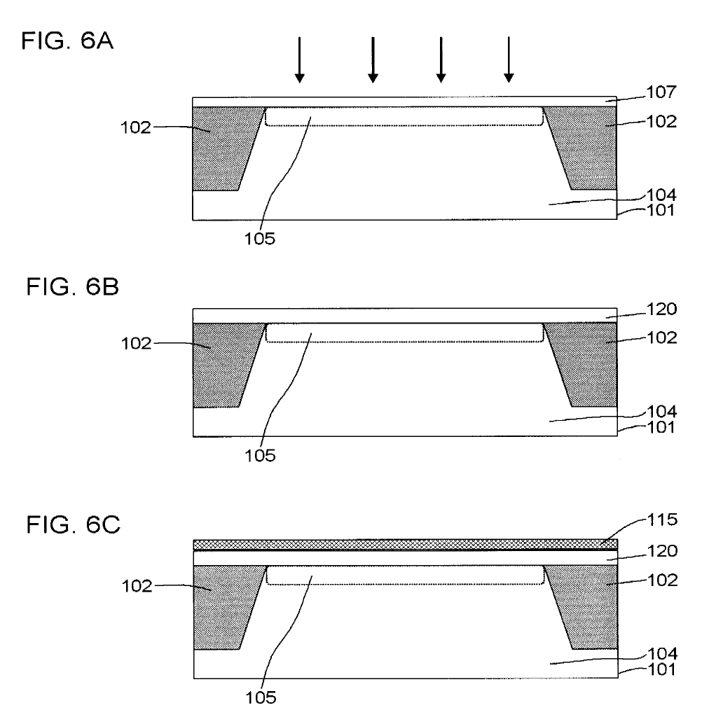

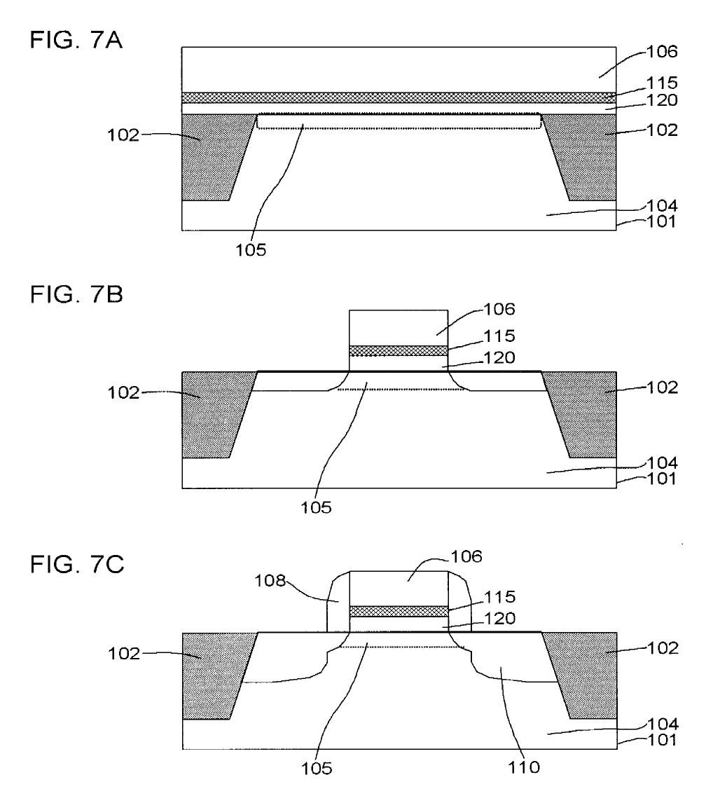

Next, the process for manufacturing the semiconductor device 100 shown in FIG. 1 will be described. FIG. 6A to FIG. 6C and FIG. 7A to FIG. 7C are cross-sectional views, illustrating an exemplary implementation of a procedure for manufacturing the semiconductor device 100 having the configuration shown in FIG. 1.

First of all, as shown in FIG. 6A, an element isolation region 102 of a shallow trench isolation is, for example, formed on a silicon substrate 101 having a principal plane of (100) plane via a known technology. The element isolation region 102 may be formed via other known process such as a local oxidation of silicon (LOCOS) process and the like.

Then, a sacrificial oxide film 107 is formed onto the surface of the silicon substrate 101. The sacrificial oxide film 107 may be obtained by thermally oxidizing the surface of the silicon substrate 101. Conditions of the thermal oxidation process may be, for example, at a processing temperature of 1,100 degree C., and for a processing time of around 100 seconds. Subsequently, an n-type impurity is ion-implanted to form an n-well 104. The n-well 104 may be formed by injecting, for example, phosphorus in conditions of 150 KeV and not less than 1×10¹³ atoms/cm² and not more than 5×10¹³ atoms/cm².

Next, an impurity of a predetermined conductivity type is ion implanted to the n-well 104 from the above of the sacrificial oxide film 107 to form a channel region 105 in vicinity of the surface layer of the n-well 104 (FIG. 6A). Quantity of a channel impurity injected to the channel region 105 may be suitably selected according to a predetermined threshold voltage of the p-type MOSFET 103.

In next, a thermal processing is conducted to activate channel impurity. Conditions of the thermal processing may be, for example, at a processing temperature of 1,000 degree C. and for a processing time of around 10 seconds. Then, the sacrificial oxide film 107 formed on the n-well 104 is removed. More specifically, the sacrificial oxide film 107 is etched off by employing a diluted hydrofluoric acid (for example, HF:H₂O=1:10), and then, the device is rinsed with pure water, and then is dried by a nitrogen blow or the like.

Subsequently, an SiO₂ film 120 serving as a gate oxide film is formed on the surface of the silicon substrate 101 via a thermal oxidation process, for example (FIG. 6B).

The thickness of the SiO₂ film 120 may be suitably selected according to the size of the p-type MOSFET 103, and is selected to be, for example, equal to or larger than 0.5 nm. Further, the thickness of the SiO₂ film 120 may be selected to be, for example, equal to or smaller than 3 nm, and preferably equal to or smaller than 2 nm, in view of more surely obtaining an advantageous effect of neutralizing positive fixed charge with Hf originated from the Hf layer 115.

Then, Hf is adsorbed over the entire upper surface of the SiO₂ film 120 (FIG. 6C). Adsorption of Hf may be achieved via, for example, a chemical vapor deposition (CVD) process, an atomic layer deposition (ALD) process, or a sputter process. Concentration of Hf must be a lower concentration of equal to or lower than 1.3×10¹⁴ atoms/cm², and in view to stably forming such metallic region of a lower concentration, a choice of a sputter process is advantageous in the above described formation processes. Thus, in the present embodiment, at least one metallic element of Hf and Zr is sputtered onto the SiO₂ film 120 to form the Hf layer 115 serving as a region containing such metallic element. In this operation, an area density of Hf in the Hf layer 115 may be selected to be equal to or lower than 1.3×10¹⁴ atoms/cm². Thereafter, an annealing process for providing an improved film quality is conducted as required.

Next, a polycrystalline silicon film 106 is deposited on the SiO₂ film 120 (FIG. 7A). Thereafter, a p-type impurity such as boron (B) may be ion implanted over the entire surface of the polycrystalline silicon film 106. The thickness of the polycrystalline silicon film may be, for example, about 130 nm.

Then, the SiO₂ film 120 and the polycrystalline silicon film 106 are selectively dry etched to process into a geometry of the gate electrode. Then, in order to form an extension region 140, which serves as an electrical coupling section of the channel region 105 with the impurity-diffused region 110 as discussed later, borondifluoride (BF₂) is injected in conditions of 2.5 keV and 5×10¹⁴ atoms/cm² in this case (FIG. 7B).

Subsequently, a side surface insulating film 108 is formed on the entire region for forming the n-well 104. Eventually, a configuration having the side surface insulating film 108 on the side surface of the gate electrode, which includes the SiO₂ film 120, the Hf layer 115 and the polycrystalline silicon film 106, is obtained. More specifically, an anisotropy etch is conducted by employing, for example, a fluorocarbon gas, so as to partially leave the side surface insulating film 108 only on the side surfaces of the SiO₂ film 120 and the polycrystalline silicon film 106.

Next, the surface layer of the n-well 104 is doped with a p-type impurity such as B through a mask of the gate electrode and the side surface insulating film 108 to form the impurity-diffused region 110. This provides forming the source region and the drain region. Boron is employed here for the p-type impurity. Conditions for the injection process may be, for example, 2 keV and 5×10¹⁴ atoms/cm² or more and 5×10¹⁵ atoms/cm² or less. Thereafter, a thermal processing is conducted in a non-oxidizing atmosphere to activate the impurity. Conditions of the thermal processing may be, for example, at a temperature of 1,000 degree C. or higher and 1,060 degree C. or lower (FIG. 7C). The above described process achieves forming the semiconductor device 100 having the p-type MOSFET 103 (FIG. 1).

Next, an appropriate range of the concentration of Hf in the Hf layer 115 provided in the interface of the SiO₂ film 120 and the polycrystalline silicon film 106 will be discussed, starting from the upper end of the concentration. Generally, a threshold voltage of a p-type MOSFET is selected to be around 0.15 to 0.45 Volt. Here, typical factors for causing a shifting of the threshold voltage includes:
(i) an increase in the threshold voltage due to an ion implantation; and
(ii) an increase in the threshold voltage due to an injection of Hf.

Concerning the above factor (ii) in these factors, the threshold voltage of the p-type MOSFET is increased, as described above in the description of the background technology. A ramp up value of the threshold voltage is increased, as the Hf concentration in the Hf layer 115 increased. When the ramp up value of the threshold voltage is relatively smaller, the threshold voltage can be suitably adjusted to a certain extent by adjusting a quantity of impurity injecting into the channel region 105. On the other hand, when ramp up quantity of the threshold voltage due to the above factor (ii) is larger, the upper limit of the ramp up quantity of the threshold voltage due to the above factor (i) is reduced, thereby causing a limitation in the ion implantation quantity.

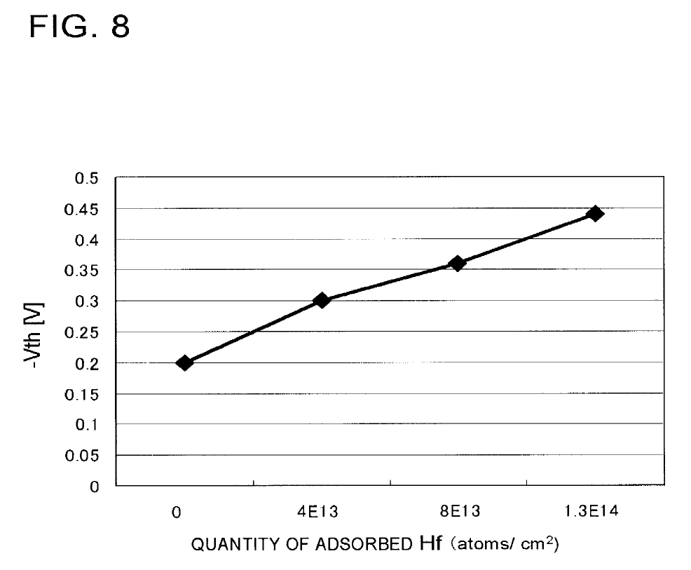

FIG. 8 is a graph, showing a relationship of the Hf concentration of Hf layer 115 with the threshold voltage of a p-type MOSFET (Vth). Concerning FIG. 8, evaluations were made by employing the semiconductor device described above in reference to FIG. 1. As can be seen from FIG. 8, transistors exhibiting the threshold voltage up to around 0.45 Volt can be obtained with a certainty, by selecting the area density of Hf to be equal to or lower than 1.3×10¹⁴ atoms/cm², and preferably equal to or lower than 8×10¹³ atoms/cm².

Besides, when the density of Hf per unit area in the Hf layer 115 is larger than 1.3×10¹⁴ atoms/cm², a tendency of considerably deteriorating a time dependent dielectric breakdown (TDDB) is exhibited. Deterioration in such TDDB can be effectively inhibited by selecting the density of Hf per unit area to be equal to or lower than 1.3×10¹⁴ atoms/cm².

Next, the appropriate range of the concentration of Hf in the Hf layer 115 concerning the lower end of the concentration will be discussed.

While the process for adsorbing Hf onto the top surface of the SiO₂ film 120 to form the Hf layer 115 typically includes a CVD process, an ALD process and a sputter process, a sputter process is the most suitable for forming the Hf layer containing Hf at a level of 10¹² atoms/cm², in view of providing an uniform Hf distribution in the in surface with a lower concentration. However, in such sputter process, Hf concentration in the Hf layer 115 may be selected to be, for example, equal to or higher than 5×10¹² atoms/cm², and preferably equal to or higher than 1×10¹³ atoms/cm², in view of forming Hf while maintaining the uniformity in the surface of 300 mm silicon wafer to ensure that Hf exists in the region for forming the polycrystalline silicon film 106.

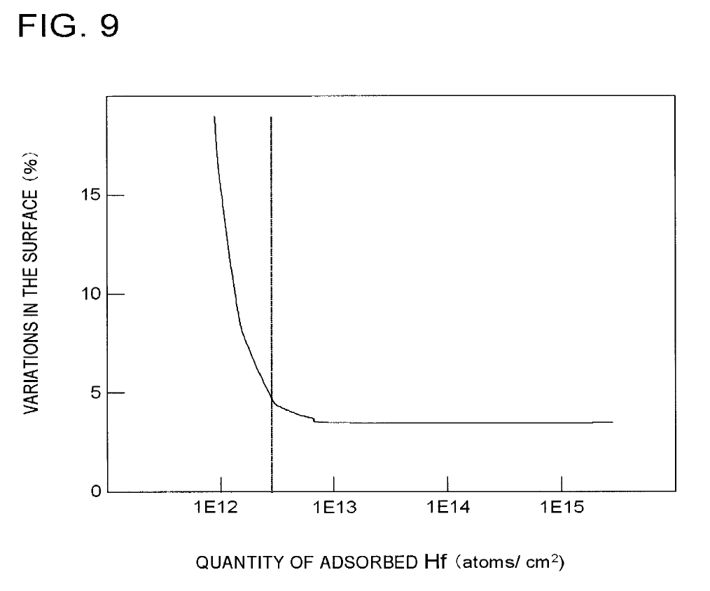

FIG. 9 is a graph, showing a variation in the Hf concentration (atoms/cm²) in the surface when Hf is sputtered onto a 300 mm silicon wafer over the concentration of Hf taken in abscissa. The variation in the concentration was obtained by the following formula (1):

variation in surface (%)=(maximum concentration−minimum concentration)/(maximum concentration+minimum concentration) (1).

According to the results shown in FIG. 9, uniformity in the concentration of Hf is rapidly deteriorated on reaching around 3×10¹² atoms/cm². Therefore, by selecting the concentration of Hf as being equal to or higher than 5×10¹² atoms/cm², a variation in the threshold voltage of the p-type MOSFET can be reduced, thereby providing further improved operating stability of the semiconductor device 100 having such p-type MOSFET 103.

In addition to above, in view of the concentration uniformity in the case of forming a film with a sputter process, the preferable lower limit of 5×10¹² atoms/cm² is not limited to Hf, and it was confirmed that similar lower limit is preferable for the process with Zr.

As described above, an improved NBTI resistance can be achieved in the p-type MOSFET 103 by providing the Hf layer 115 containing Hf in the interface of the SiO₂ film 120 and the polycrystalline silicon film 106 at an area density of equal to or lower than 1.3×10¹⁴ atoms/cm².

Further, while the threshold voltage is remarkably increased when a hafnium silicate (Hf silicate) film, which is a high dielectric constant film, is provided for serving as a gate insulating film, the configuration of the present embodiment can provide an improved NBTI resistance while inhibiting an increase in the threshold voltage, by providing the Hf layer 115 having an area density of Hf, which is much lower than an area density of Hf in the Hf silicate film.

Determination of a quantity of Hf within the concentration range as described above is made, in consideration of the transistor design of the whole semiconductor device 100, based on a relationship of Hf absorbed amount and a variation in the threshold voltage, which have been acquired in advance. Larger quantity of Hf adhesion provides further improvement in the NBTI resistance, while providing more considerable increase in the threshold voltage, and therefore a suitable establishment of the operating conditions depending on the application of the semiconductor device is required.

While the configuration having the Hf layer 115 provided in the interface of the polycrystalline silicon film 106 and the SiO₂ film 120 in the p-type MOSFET 103 has been illustrated, at least one of Hf and Zr may be contained as a trace amount of metallic element included in the metal-containing region provided in the interface of the SiO₂ film 120 and the polycrystalline silicon film 106 in the present embodiment and the following embodiments.

When Hf and Zr are present in the interface of the SiO₂ film 120 and the polycrystalline silicon film 106, sum of the sheet concentrations of Hf and Zr in the metallic layer may be equal to or lower than 1.3×10¹⁴ atoms/cm².

### Second Embodiment

Configuration of a semiconductor device according to the present embodiment is generally similar to the configuration of the semiconductor device 100 of first embodiment, except that the metallic layer containing at least one of Hf and Zr is included in the gate insulating film, and that a multiple-layered configuration of, starting from the side of the semiconductor substrate, a first gate insulating film, a Hf layer, a second gate insulating film and a gate electrode, is included. In the present embodiment, descriptions will be made focusing on different aspects from first embodiment.

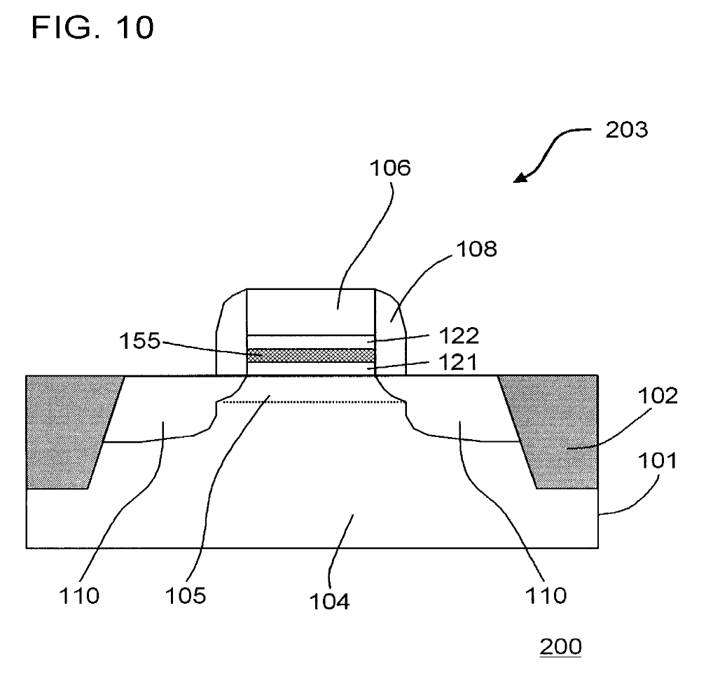

FIG. 10 is a cross-sectional view, schematically illustrating a configuration of a semiconductor device 200 according to the present embodiment.

The semiconductor device 200 includes a silicon substrate 101 and p-type MOSFET 203 provided on the silicon substrate 101. Further, a circumference portion of the p-type MOSFET 203 is provided with an element isolation region 102. In the p-type MOSFET 203, a pair of impurity-diffused regions 110 are provided in an N-well 104, which is provided in the silicon substrate 101 and has a n-type conductivity, and a channel region 105 is formed between these impurity-diffused regions. The impurity-diffused regions 110 are diffusion layers doped with a p-type impurity in the surface of the n-well 104. One will be a source region, and the other will be a drain region. Further, extension regions are provided in the n-well 104. Such configuration is similar to that shown in FIG. 1.

A first gate insulating film (first SiO₂ film 121), serving as a gate insulating film, is provided on the channel region 105, and an Hf layer 155 is provided so as to be in contact with the upper portion of the first SiO₂ film 121. The Hf layer 155 is a metallic layer, containing Hf at a concentration of equal to or lower than 1.3×10¹⁴ atoms/cm². The Hf layer 155 is provided in, for example, the entire interface of the first SiO₂ film 121 and the second gate insulating film (second SiO₂ film 122.) This can more stably provide an advantageous effect of inhibiting the NBTI.

The thickness of the Hf layer 155 is equal to or shorter than 1 nm, for example. Further, atomic Hf is present in a scattered manner in the Hf layer 155. Thus, an average thickness of the Hf layer 155 in the cross-sectional view along the gate length direction may be smaller than a thickness equivalent to a layer of single atom.

The Hf layer 155 may be formed via any of a CVD process, an ALD process and a sputter process, and more specifically, a sputter process is employed here, similarly as in first embodiment. Further, the second SiO₂ film 122 is provided so as to be in contact with the top surface of the Hf layer 155. Subsequently, the polycrystalline silicon film 106 is provided so as to be in contact with the upper portion of the second SiO₂ film 122. The polycrystalline silicon film 106 is a gate electrode film, and is doped with a p-type impurity such as boron (B) and the like.

The present inventors have confirmed that the configuration of the present embodiment shown in FIG. 10 exhibits an advantageous effect of achieving an improvement in the NBTI resistance in the p-type MOSFET 203, similarly as the configuration of first embodiment shown in FIG. 1. It is considered that the reasons are, similarly as in first embodiment, either one or both of: 1) Hf or Hf compound functions as an electron trap or an electron scavenger, which serves as neutralizing the influence of positive fixed charge generated due to the NBTI; and 2) electric field applied to the gate insulating film is reduced due to Fermi level pinning as the gate electrode is the polycrystalline silicon film 106, leading to reducing an accumulation of positive fixed charge.

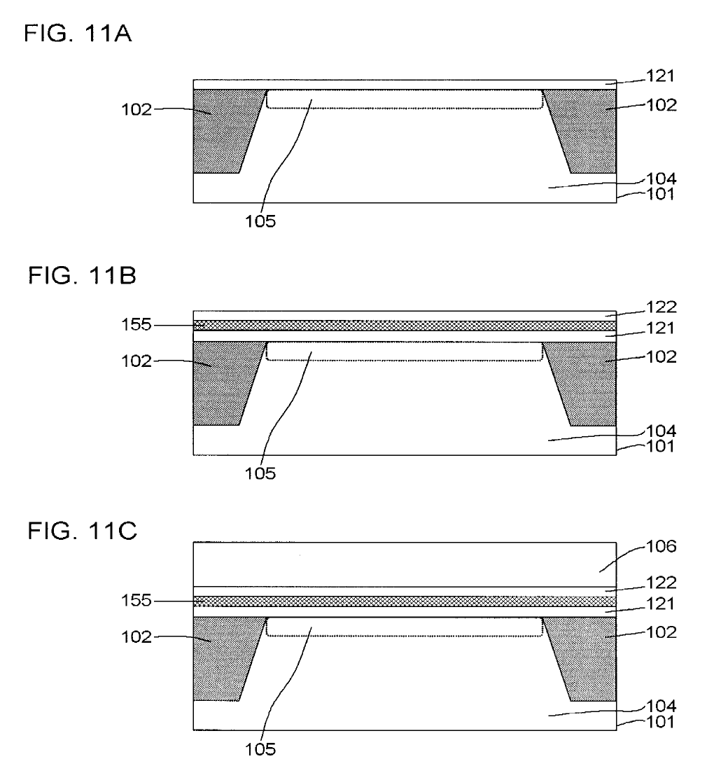

Next, a process for manufacturing the semiconductor device 200 shown in FIG. 10 will be described by focusing on dissimilarities with the semiconductor device 100. FIG. 11A to FIG. 11C are cross-sectional views, illustrating an example of a procedure for manufacturing the semiconductor device 200 having the configuration shown in FIG. 10.

FIG. 11A is similar to FIG. 6B, and shows a condition, in which the element isolation region 102, the n-well 104, the channel region 105 and the first SiO₂ film 121 are formed in the silicon substrate 101.

While there is no particular limitation in the lower limit of the film thickness of the first SiO₂ film 121, the thickness may be, for example, equal to or larger than 0.5 nm, and preferably equal to or larger than 1 nm, in view of the depositing stability. Further, the thickness of the first SiO₂ film 121 may be selected to be equal to or smaller than 10 nm, and preferably equal to or smaller than 9 nm.

Then, Hf is also adsorbed onto the first SiO₂ film 121 via a sputter process to form the Hf layer 155 that serves as a metallic layer, in the present embodiment. Thereafter, an annealing process for providing an improved film quality is conducted as required. Concentration of Hf in the Hf layer 155 may be selected to be 5×10¹² atoms/cm² or more and 1.3×10¹⁴ atoms/cm² or less. Determination of a quantity of adsorbed Hf within the such concentration range is made, in consideration of an increase in the threshold voltage of the p-type MOSFET 203, and in view of the transistor design of the whole semiconductor device 200.

Further, the second SiO₂ film 122 serving as the second gate oxide film is formed on the surface of the Hf layer 115. The second SiO₂ film 122, may be formed via a thermal oxidation process, for example (FIG. 11B). While there is no particular limitation in the lower limit of the film thickness of the second SiO₂ film 122, the thickness may be, for example, equal to or larger than 0.5 nm, and preferably equal to or larger than 1 nm, in view of the depositing stability. Further, the thickness of the second SiO₂ film 122 may be selected to be equal to or smaller than 10 nm, and preferably equal to or smaller than 9 nm.

Further, in view of obtaining an improvement in the NBTI resistance with further certainty, total film thickness of the first SiO₂ film 121 and the second SiO₂ film 122 may be selected to be, for example, equal to or smaller than 3 nm, and preferably equal to or smaller than 2 nm.

Subsequently, the polycrystalline silicon film 106 is deposited via a CVD process, and then, a p-type impurity such as B may be ion implanted over the entire surface of the polycrystalline silicon film 106. The thickness of the polycrystalline silicon film may be, for example, about 130 nm. In this condition, the structure of FIG. 11C is obtained. Operations in the process for manufacturing the semiconductor device 200 thereafter are similar to that for the semiconductor device 100 in first embodiment, and thus the descriptions are not presented.

While the preferred embodiments of the present invention have been described above in reference to the annexed figures, it should be understood that the disclosures above are presented for the purpose of illustrating the present invention, and various configurations other than the above described configurations can also be adopted.

For example, while the exemplary implementation having the gate electrode composed of the polycrystalline silicon film 106 has been described in the above-mentioned embodiments, the gate electrode is not particularly limited to that containing silicon such as polycrystalline silicon.

Further, while the exemplary implementation employing the SiO₂ film 120 for the gate insulating film has been described in the above-mentioned embodiments, the gate insulating film is not limited to the oxide film, and an oxide film, an oxynitride film or the like may alternatively be employed.

Further, in the above-mentioned embodiments, the concentration of metallic element existing in the Hf layer may be measured via, for example, an electron energy loss spectroscopy (EELS), a secondary ion mass spectrometry (SIMS) and the like.

It is apparent that the present invention is not limited to the above embodiment, and may be modified and changed without departing from the scope and spirit of the invention.

What is claimed is:

1. A semiconductor device, comprising a p-type field effect transistor, said p-type field effect transistor comprising:
a semiconductor substrate;
a gate insulating film provided so as to be in contact with an upper portion of said semiconductor substrate; and
a gate electrode provided so as to be in contact with an upper portion of said gate insulating film,
wherein a region is included in said gate insulating film or in an interface between said gate insulating film and said gate electrode, said region containing at least one metallic element of hafnium (Hf) and zirconium (Zr) at an area density of not higher than 1.3×10¹⁴ atoms/cm².

2. The semiconductor device as set forth in claim 1, wherein said metallic element is included in said region at an area density of not higher than 5×10¹² atoms/cm².

3. The semiconductor device as set forth in claim 1, wherein said gate electrode includes silicon.

4. The semiconductor device as set forth in claim 1, wherein said region is a layer containing said metallic element, and a thickness of said layer is equal to or lower than 1 nm.

5. The semiconductor device as set forth in claim 4, wherein said layer is provided in an interface between said gate insulating film and said gate electrode.

6. The semiconductor device as set forth in claim 5, wherein said gate insulating film is a silicon dioxide (SiO₂) film.

7. The semiconductor device as set forth in claim 4, wherein said layer is provided in said gate insulating film.

8. The semiconductor device as set forth in claim 7, wherein said gate insulating film comprises:
a first gate insulating film provided so as to be in contact with an upper portion of said semiconductor substrate;
said layer provided so as to be in contact with an upper portion of said first gate insulating film; and
a second gate insulating film provided so as to be in contact with an upper portion of said layer.

9. The semiconductor device as set forth in claim 8, wherein both of said first gate insulating film and said second gate insulating film are SiO₂ films.

10. A method for manufacturing the semiconductor device as set forth in claim 1, comprising:
forming said gate insulating film on said semiconductor substrate;
sputtering at least one metallic element of hafnium (Hf) and zirconium (Zr) onto said gate insulating film to form a region containing said metallic element; and
forming a gate electrode film on said gate insulating film that is provided with said region,
wherein, in said forming said region containing said metallic element, an area density of said metallic element in said region is equal to or lower than 1.3×10¹⁴ atoms/cm².

11. A method for manufacturing the semiconductor device as set forth in claim 1, comprising:
forming a first gate insulating film on said semiconductor substrate;
sputtering at least one metallic element of hafnium (Hf) and zirconium (Zr) onto said first gate insulating film to form a region containing said metallic element;
forming a second gate insulating film on said first gate insulating film that is provided with said region; and
forming a gate electrode film on said second gate insulating film,
wherein, in said forming said region containing said metallic element, an area density of said metallic element in said region is equal to or lower than 1.3×10¹⁴ atoms/cm².
